(19) United States
(12) Patent Application Publication
(10) Pub. No.: US 2024/0413818 A1
(43) Pub. Date: Dec. 12, 2024

(54) HIGH VOLTAGE SERIES MOSFET SWITCHING CIRCUIT

(71) Applicant: SHEFFIELD HALLAM UNIVERSITY, Sheffield South Yorkshire (GB)

(72) Inventor: Walid Issa, Sheffield South Yorkshire (GB)

(73) Assignee: SHEFFIELD HALLAM UNIVERSITY, Sheffield South Yorkshire (GB)

(21) Appl. No.: 18/702,232

(22) PCT Filed: Oct. 19, 2022
(86) PCT No.: PCT/EP2022/079134

§ 371 Date: Apr. 17, 2024

(30) Foreign Application Priority Data
Oct. 21, 2021 (GB) 2115166.7

(51) Int. Cl. H03K 17/16

(52) U.S. Cl. CPC H03K 17/161

(57) ABSTRACT

The present invention provides a modular power switching circuit (100) having a plurality of modular cells (104) each of which cascades activation to the adjacent cell to handle high voltages via switched capacitors.

### TECHNICAL FIELD

The present invention is concerned with a high voltage series MOSFET switching circuit. More specifically, the present invention is concerned with a circuit design utilising multiple, series connected MOSFETs to switch voltages in the order of kV.

### BACKGROUND ART

Metal oxide semiconductor field effect transistors (MOSFETs) are well known in the field of power electronics. They allow a low voltage input to switch a high voltage signal. For example, a typical SiC MOSFET can be switched with a voltage between gate and source (V_{GS}) of a few volts, and can accept a switched voltage between drain and source (V_{DS}) of 1.2 kV.

The most common type of MOSFETs used in power electronics is the n-channel enhancement mode MOSFET. Historically, silicon has been the semiconductor of choice for MOSFETs.

In recent years, wide-bandgap semiconductors devices have enabled improvements in the power electronics fields applications. At the time when silicon devices are close to the limitation of the material, silicon carbide (SiC) materials offer high switching speed, high breakdown voltage and high thermal conductivity, making it a superior material to silicon. SiC MOSFETs are a promising alternative to Si in medium and high voltage power electronics applications. Gallium nitride (GaN) MOSFETs are also a potential alternative to Si for high current applications due to its low on-state resistance.

The adoption of high voltages in various applications such as electric vehicles, renewable energy and energy storage systems is increasing. Unfortunately, power electronics switches incorporating SiC MOSFETs are lagging. SiC MOSFETs have high switching capabilities and lower power dissipation. The existing commercial SiC MOSFETs are rated at either 1.2 and 1.7 kV at the most. Some higher voltage SiC switches are in the development stage and, even if available commercially, would be costly.

The aim of the present invention is to achieve a commercially and technically feasible power electronics switching circuit for MOSFETs at voltages in the order of kVs.

Solutions proposed in the prior art include the idea of utilising multiple isolated-driven series MOSFETs to handle the increased voltage. One drawback with such systems is the need to provide a gate driver for each MOSFET. This can make it far from compact, as is required by most applications.

Another concern while driving series MOSFET devices is the off-state voltage balancing during both steady state and dynamic transition. The uneven leakage current between series MOSFETs is the main reason behind the unbalanced voltage distribution.

Equal parallel resistors across series MOSFETs will not always guarantee a balanced voltage if the leakage current is significant.

A still further concern is the potential for false turn-on, particularly when the temperature of the MOSFET increases. This is because increased temperature tends to reduce the threshold voltage of the MOSFET. This is particularly true for SiC MOSFETs which tend to have a lower gate capacitance compared to Si.

Prior art systems have attempted to utilise a single gate driver to drive a plurality of series-connected MOSFETs.

For example, the paper “A Compact Gate Control and Voltage-Balancing Circuit for Series-Connected SiC MOSFETs and Its Application in a DC Breaker” Y. Ren et al, IEEE Trans. Industrial Electron., vol. 64, no. 10, pp. 8299-8309, Oct. 2017 discloses a compact circuit combining function of gate control and voltage balancing for series-connected silicon carbide (SiC) MOSFETs.

A signal is initiated by the activation of the gate driver, using the change of voltage levels across the capacitor terminals. The level of generated signal by the capacitor is sufficient to reach the threshold voltage of the next MOSFET, which is thereby activated and so on.

A problem with this approach, known as capacitive coupling, is that the capacitor will generate a current based on

$$I = C \frac{dV}{dt} ,$$

so current is proportional to the change in voltage. By cascading this to several MOSFETs, dV/dt will eventually fade out because of the non-ideal capacitor which exhibits losses in the form of small resistances dropping voltages.

The paper “A Single Gate Driver Based Solid-State Circuit Breaker Using Series Connected SiC MOSFETs”, Y. Ren, et al, IEEE Trans. Power Electron., vol. 34, no. 3, pp. 2002-2006, Mar. 2019 describes a circuit breaker arrangement in which two series connected MOSFETs are provided in order to withstand high dc-bus voltages. The paper itself states that a problem with such arrangements is that “The balanced voltage distribution across these series connected devices is the most challenging technical issue.”. A drawback with this device is that it is not truly modular—each of the MOSFET devices has a different driving circuit.

The paper “A Compact Series-Connected SiC MOSFETs Module and Its Application in High Voltage Nanosecond Pulse Generator”, L Pang et al, IEEE Trans. Industrial Electron., vol. 66, no. 12, pp. 9238-9247, Dec. 2019 describes a pulse generator featuring series connected MOSFETs having a single gate driver. The paper proposes capacitive coupling between the respective MOSFETs. A problem with this approach is that the driving signal becomes attenuated as more MOSFETs are added.

It is an aim of the present invention to overcome, or at least mitigate, the aforementioned problems in the prior art.

### SUMMARY OF INVENTION

According to a first aspect of the present invention there is provided a switching circuit comprising:
a plurality of n MOSFET cells (n≥2), each MOSFET cell comprising:
   a gate terminal, a source terminal, a drain terminal and a cascading terminal;
a MOSFET (MN) having a gate node (GN), source node (SN) and drain node (DN) connected to the gate, source and drain terminals respectively;
a gate resistor (RG) between the gate node and a gate terminal;
a balance capacitor (CB) between the source node and the cascading terminal;
a balance resistor (RB) in parallel with the balance capacitor;
   a gate driver connected to drive the gate node (G1) of the first MOSFET cell;
   wherein:
the drain terminal of each of the MOSFET cells (N=1 . . . (n-1)) is connected to the source terminal of an adjacent, MOSFET cell (N=2 . . . n);
the cascading terminal of each of the MOSFET cells (N=1 . . . (n-1)) is connected to the gate terminal of an adjacent, MOSFET cell (N=2 . . . n); and,
the drain terminal and cascading terminal of the nth MOSFET cell (N=n) is connected to a supply voltage (VS);
   such that:
in an off state, the supply voltage (VS) provided across the cascading terminal of the nth cell and the source terminal of the first cell charges the balance capacitor CB of each cell; and,
upon provision of a gate driving voltage to the gate terminal of the first cell (N=1) to activate the MOSFET (M1) of the first cell, the balance capacitor (C1) discharges to the gate terminal of the adjacent cell to switch on the MOSFET (M2) thereof.

Advantageously the present invention utilises a switched capacitor, in which the balance capacitor of each cell is charged during the off state, and subsequently discharged through the gate-source of the next cell MOSFET M_{N+1} via the cascading terminal when the cell MOSFET M_{N}'s drain-source current path is closed. Similarly, this happens to each cell in series. Unlike the prior art capacitive coupling concept, it is not the gate driver signal that is passed from capacitor to capacitor (cell to cell), rather each cell provides the required gate driving voltage via its own capacitor charged by the supply voltage.

In particular, the present invention:
Provides bipolar driving for all MOSFETs in series;
Achieves balanced voltages across all MOSFETs when they are turned off;
Achieves switching for all MOSFETs less than 100 ns;
Is a modular design so can be duplicated for different number of series MOSFETs;
All components are passive low cost which facilitate compact and robust design.

Unlike some prior art devices, the present invention does not require separate power supplied for each of the MOSFET cells. The entire system is powered by the load current, and switched by a single gate driver at the lowest module.

Preferably, n≥2, and upon activation of the MOSFET (M₂) of the second cell, the balance capacitor (C₂) discharges to the gate terminal of the adjacent cell to switch the MOSFET (M3) thereof

Preferably each MOSFET cell comprises a first diode directed from the source node (S_{N}) to the gate node (G_{N}). Preferably each MOSFET cell comprises a second, Zener diode directed from the gate node (G_{N}) to the source node (S_{N}). The first diode may be a Zener diode.

Advantageously, the provision of two back-to back Zener diodes between the gate and source nodes of the MOSFET achieves a robust negative bias for MOSFETS in ‘off’ state, reducing the tendency to falsely turn on.

Preferably each MOSFET cell comprises a supply diode DS directed from the gate terminal to the cascading terminal. Preferably the supply diode DS can be selectively disconnected in the final cell (N-n). Each MOSFET cell from N=1 to N=(n-1) may comprise a supply diode DS directed from the gate terminal to the cascading terminal. The final cell N-n (a “capping cell”) does not require such a diode.

In one embodiment the balance capacitor of the MOSFET cell N-n has a capacitance at least twice as high as the balance capacitors of the MOSFET cells N=1 to N=(n-1). Preferably the capacitance of the balance capacitors of the MOSFET cells N=1 to N=(n-1) are identical.

Preferably each MOSFET cell comprises a balance diode DB in series with the balance resistor RB, the balance diode directed from the cascading terminal to the source node.

Preferably each MOSFET cell comprises a second balance resistor DBd, and a second balance diode DBd in series with the balance resistor RBd, the second balance diode DBd being directed from the source node to the cascading terminal, wherein the balancing resistors have different resistances.

Preferably the MOSFETs are SiC or GaN MOSFETs.

Preferably the MOSFETs are enhancement mode n-channel MOSFETs.

Preferably the supply voltage VS>2 kV.

According to a second aspect of the invention there is provided a switching circuit cell comprising:
a gate terminal, a source terminal, a drain terminal and a cascading terminal;
a MOSFET (MN) having a gate node (GN), source node (SN) and drain node (DN) connected to the gate, source and drain terminals respectively;
a gate resistor (RG) between the gate node and a gate terminal;
a balance capacitor (CB) between the source node and the cascading terminal;
a balance resistor (RB) in parallel with the balance capacitor;
   a gate driver connected to drive the gate node (G1) of the first MOSFET cell;
   wherein the switching circuit cell is configured to be connected with a gate driver and at least one like cell in series to provide a high voltage switching circuit.

### BRIEF DESCRIPTION OF DRAWINGS

An embodiment of the present invention will now be described with reference to the following figure in which:

FIG. 1a is a diagram of a first embodiment of a switching circuit according to the present invention;

FIG. 1b is a detail view of a part of the circuit of FIG. 1a;

FIG. 2 is a diagram of part of a second embodiment of a switching circuit according to the present invention;

FIG. 3 is a diagram of part of a third embodiment of a switching circuit according to the present invention;

FIG. 4a is a diagram of a fourth embodiment of a switching circuit according to the present invention;

FIG. 4b is a detail view of a part of the circuit of FIG. 4a;

FIGS. 4c to 4g are operation diagrams;

FIG. 4h is a series of graphs of the operating characteristics of the circuit of FIG. 4a;

FIGS. 4i to 4l are operation diagrams;

FIG. 5 is a diagram of a part of a fifth embodiment of a switching circuit according to the present invention;

FIG. 6 is a diagram of a sixth embodiment of a switching circuit according to the present invention;

FIG. 7 is a diagram of a sixth embodiment of a switching circuit according to the present invention; and,

FIG. 8 is a diagram of an eighth embodiment of a switching circuit according to the present invention.

### DESCRIPTION OF THE FIRST EMBODIMENT

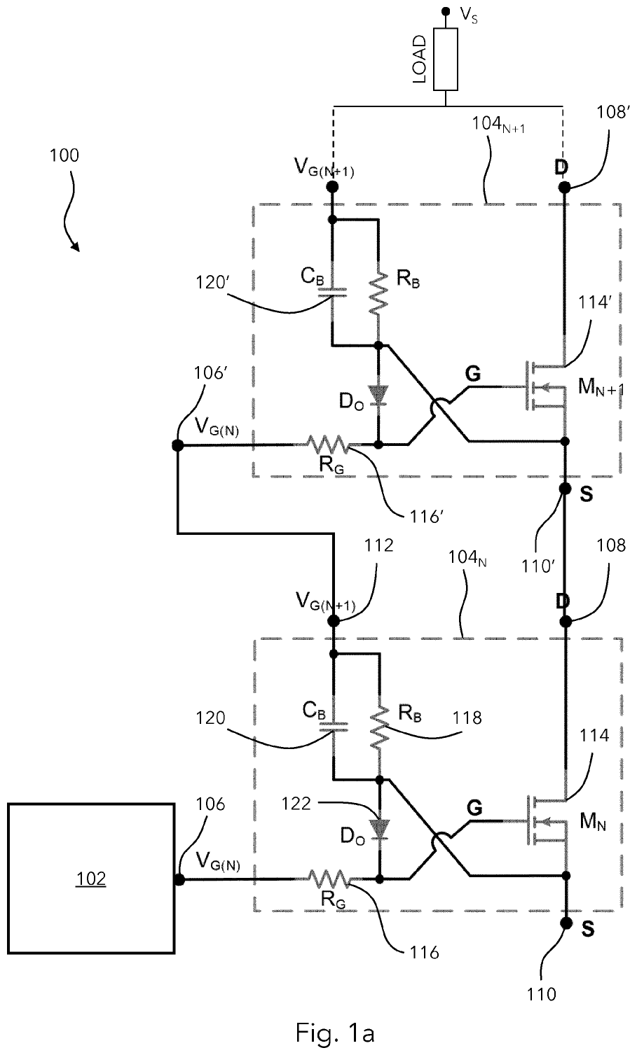

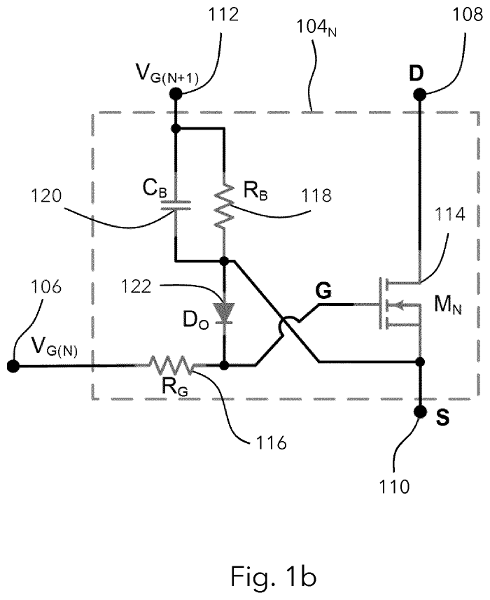

The first embodiment is shown in FIGS. 1a and 1b.

### Configuration

Referring to FIG. 1a, there is shown a diagram of a first switching circuit 100 in accordance with the present invention. The circuit 100 comprises a MOSFET gate driver 102, first driving cell 104_{N} and a second driving cell 104_{N+1}.

The MOSFET gate driver 102 is known in the art and will not be described in detail here, except to say that it is a circuit configured to create or deliver a pulse/square wave input to the first cell 104_{N} at V_{on-drive} to turn on (positive voltage) and V_{off-drive} (negative voltage) to turn off.

The cells 104_{N}, 104_{N+1} . . . 104ₙ are identical (i.e. are interconnectable modules) and cell 104_{N} is shown in more detail in FIG. 1b. Each cell circuit 104_{N} has four terminals:
Cell gate terminal 106;
Cell drain terminal 108;
Cell source terminal 110; and,
Cascading terminal 112.

The cell 104_{N} comprises a SiC n-channel enhancement mode MOSFET M_{N} 114 having gate node G, drain node D and source node S. The MOSFET gate terminal G is connected to the cell gate terminal 106 via a gate resistor R_{G}. The MOSFET drain and source terminals D, S are connected to the cell drain and source terminals 108, 110 respectively. The MOSFET source terminal S is also connected to the cell cascading terminal 112 via a balance resistor R_{B} and a balance capacitor C_{B} in parallel.

A diode Dₒ pointing towards the gate G (i.e. with a lower resistance towards the gate G) is connected between a first position between the balance capacitor/resistor and the MOSFET source terminal S, and a second position between the gate resistor R_{G} and the MOSFET gate terminal G.

It will be noted that the cell 104_{N} (aside from the MOSFET 114) is constructed from basic passive components (two resistors, one diode and one capacitor). This provides reliability to the design against variations in temperature, frequency and voltages spikes and doesn't include magnetic components that might produce EMI issues and add complexity.

The footprint and selection of these components can be optimized to achieve a compact design. Each cell can provide bipolar driving, gate protection and ON and OFF-state voltage balancing.

### Operation

### OFF—Steady State Operation

All MOSFET switches are off and sharing the supply voltage as Vs/n (note that n=2 in this embodiment). In the steady state, the supply voltage Vₛ acts to charge the balance capacitors C_{B}.

### Turn on Transition

The explained analysis in this section for the voltage and current waveforms and switching transitions are based on a clamped inductive load in the commonly used double pulse testing. The turn-on transition is divided into two main stages.

### Stage 1

It is assumed that before this stage starts, all switches are off and sharing the supply voltage as Vs/n (note that n=2 in this embodiment) and the V_{GS} is at off driving voltage i.e. sub-threshold.

It will be noted that each capacitor C_{B} is initially in a charged state from the supply voltage Vₛ.

A turn-on signal V_{on-drive} is given by the gate driver 102 to the first MOSFET, M_{N}. The gate voltage starts rising passing the threshold voltage and the MOSFETs are still in the off state. The voltage across the MOSFET M_{N}, V_{DSM(N)} is at high level and the current I_{DM(N)} is zero. The gate current is dominated by the current through the resistor R_{GM(N)}.

### Stage 2

At the beginning of stage 2, the current I_{DM(N)} starts to rise while the voltage V_{DSM(N)} of MOSFET My starts to fall bringing the source node of MOSFET M_{N+1} to a lower voltage than its drain node.

At the same time, the capacitor C_{BM(N)} will have a new current path to discharge through the gate to source capacitance of M_{N+1} allowing the V_{GSM(N+1)} to rise followed by a rise in its current I_{DM(N+1)} and a fall in its voltage V_{DSM(N+1)}. The discharging current of the capacitor C_{BM(N)} is determined by the change in voltage at the source node of M_{N+1}, i.e. caused by the R_{ds(on)M(N)} and the gate capacitance charge of M_{N+1}, in addition, to the value of R_{GM(N+1)}.

### ON—Steady State Operation

At steady state and when all MOSFETs are on, all of the MOSFETs are represented by their respective on-state resistances.

### Turn Off Transition

Turn-off is divided into two stages.

### Stage 3

Before this stage, it is assumed that all MOSFETs are in on-steady state and they are conducting the current from the top drain node to the bottom source node through their on-state resistances. At this stage, a negative driving voltage is generated by the driver, V_{off-drive}, and discharging the gate capacitance C_{GSM(N)} through R_{GM(N)}.

### Stage 4

The gate voltage V_{GSM(N)} dropped to a level below the threshold voltage and the voltage V_{DSM(N)} starts rising while the current I_{DM(N)} starts dropping turning off the MOSFET M(N) completely. The I_{D} through MOSFET M_{N} is commutated through the diode D₀, the gate resistance R_{GM(N+1)} and the balance resistance R_{BM(N)} to the source. The voltage drop across the diode D_{o(M+1)} will start turning off the M_{N+1} MOSFET.

### DESCRIPTION OF THE SECOND EMBODIMENT

### Configuration

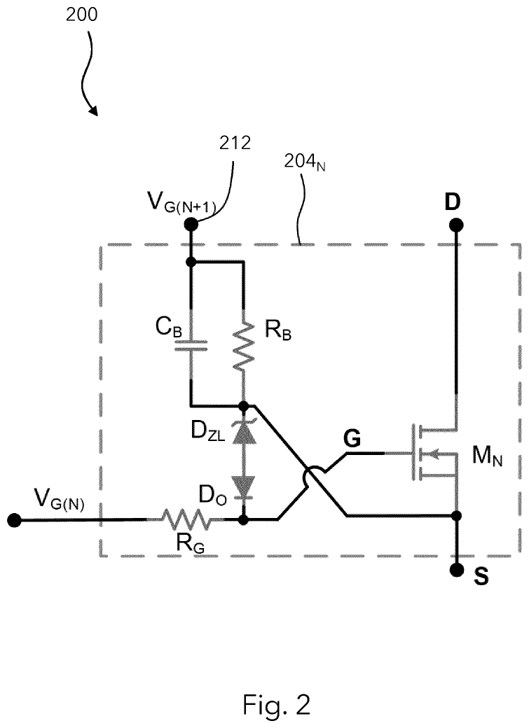

Referring to FIG. 2 a cell circuit 204_{N} is shown. All reference numerals are per the circuit 104_{N} but 100 greater.

As an alternative embodiment to 104_{N}. In this instance, the diode Dₒ is supported with a Zener diode D_{ZL} having a forward direction from the gate G of MOSFET M_{N} towards the source S of MOSFET M_{N}.

### Operation

It is known that higher junction temperature of the SiC MOSFETs leads to lower gate threshold voltage and a small voltage on the gate might turn on the MOSFET and causes a false turn on, in particular, SiC MOSFETs have less gate capacitance than Si. A negative gate drive voltage is recommended to achieve a stable and reliable off-state of the SiC MOSFETs. In this embodiment, the supply voltage reverse biases the Zener diode D_{ZL}, which results in a significant negative voltage (for example −5V) at the gate.

### DESCRIPTION OF THE THIRD EMBODIMENT

### Configuration

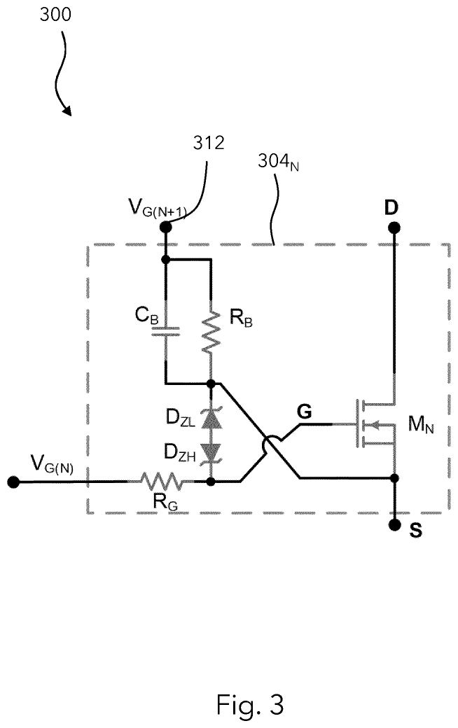

Referring to FIG. 3 a cell circuit 304_{N} is shown. All reference numerals are per the circuit 204_{N} but 100 greater.

In this instance, the diode Dₒ is replaced with a Zener diode D_{ZH} between the Zener diode D_{ZL} and the gate G. This Zener diode has a forward direction from the cascading terminal 212 towards the gate G of MOSFET M_{N}.

### Operation

The advantage of such an arrangement is that it provides protection for the MOSFET gate from overvoltage while driving. The additional Zener diode will clip spikes or higher voltages. More than 20V for Si or SIC MOSFETs might damage them.

It will be noted that the additional Zener D_{ZH} provides a voltage drop from source to gate in the off-state (i.e. when forward biased with the supply current). The drop is typically around 0.5V to 0.7V. To reliably avoid false turn-on, the Zener D_{ZL} is employed to maintain the off-state voltage at below −3V (and preferably at −5V to −6V). Therefore if the diode D_{ZH} is utilised to avoid overvoltage, it is advantageous to pair it with Zener D_{ZL} to avoid false turn on in the off state.

### DESCRIPTION OF THE FOURTH EMBODIMENT

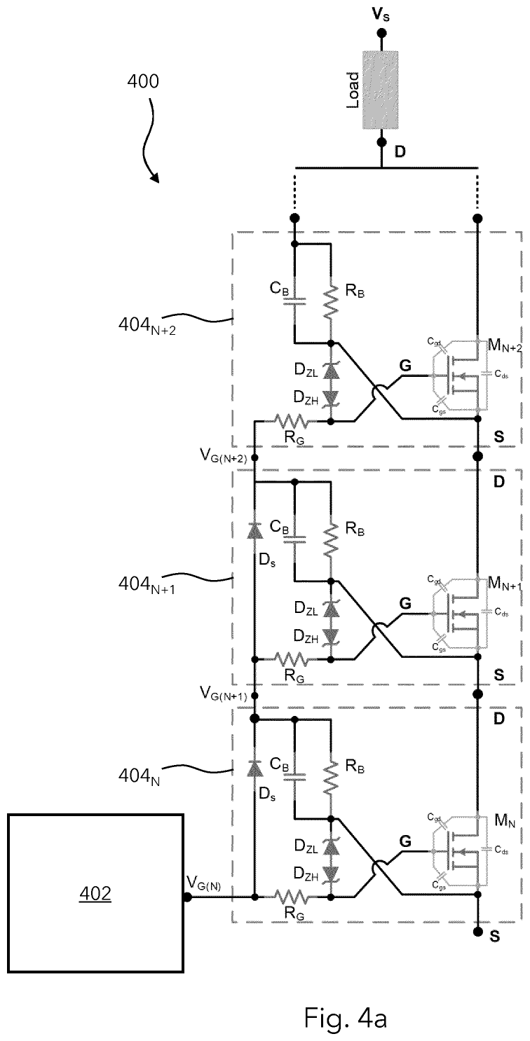

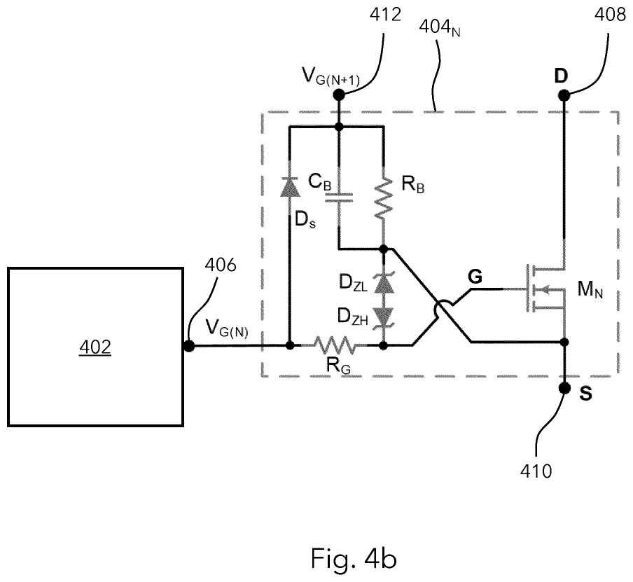

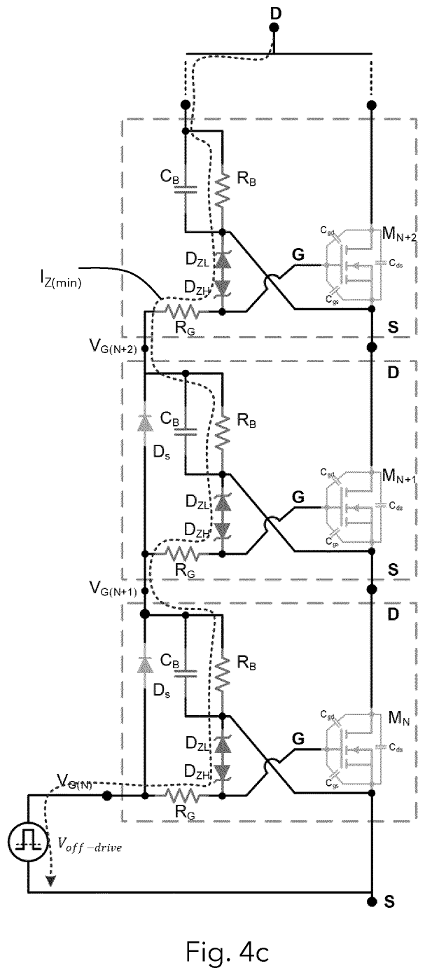

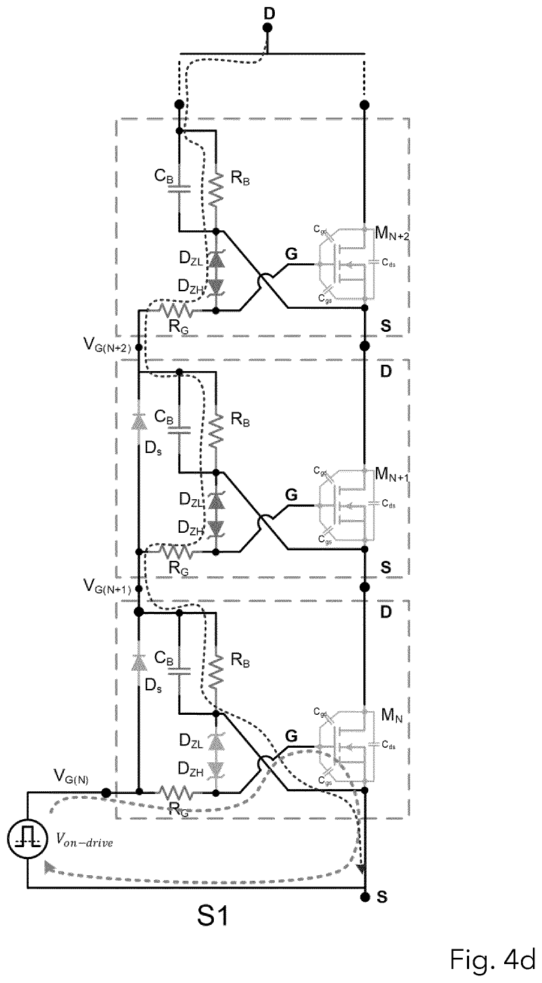

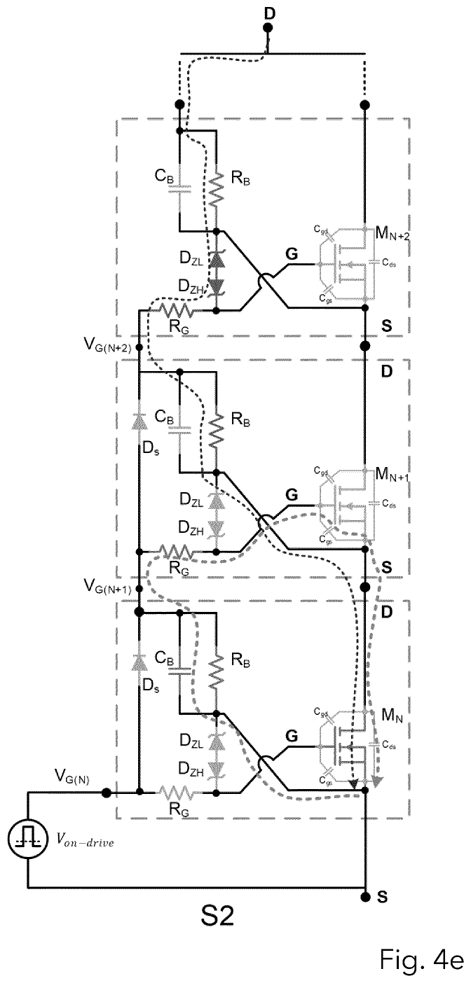

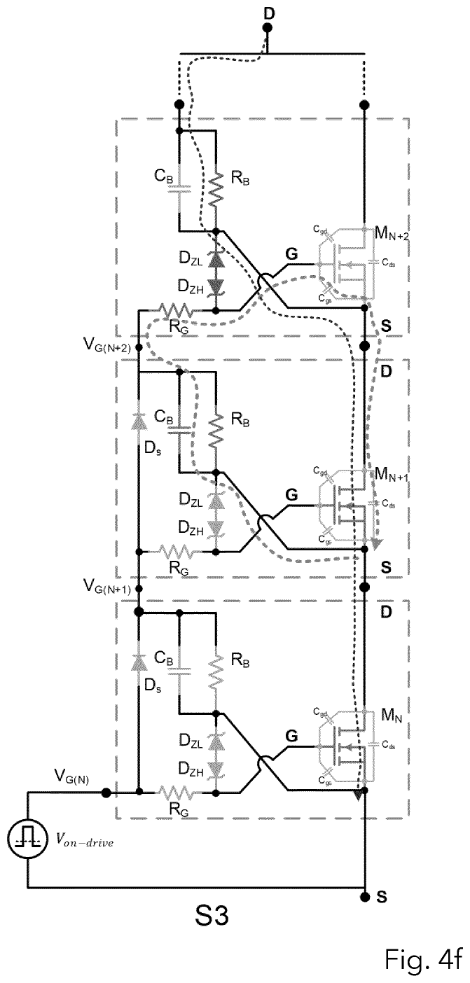

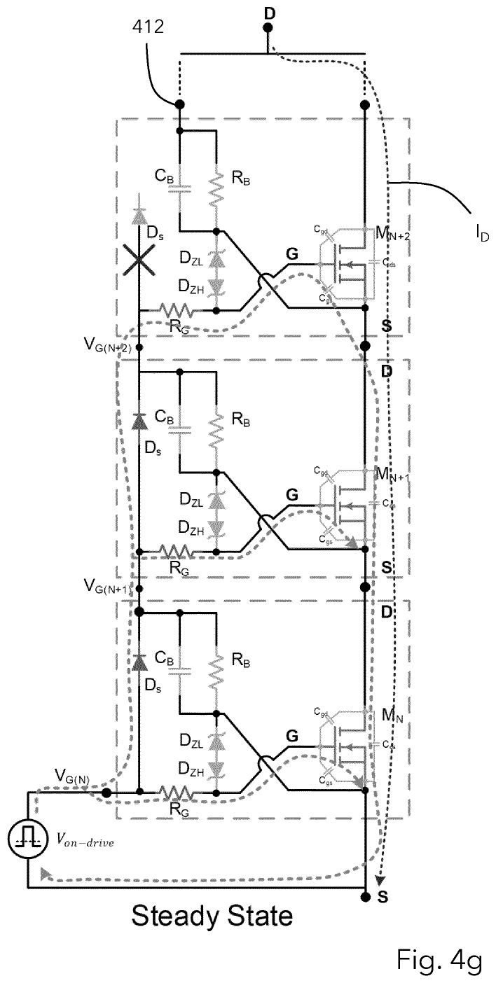

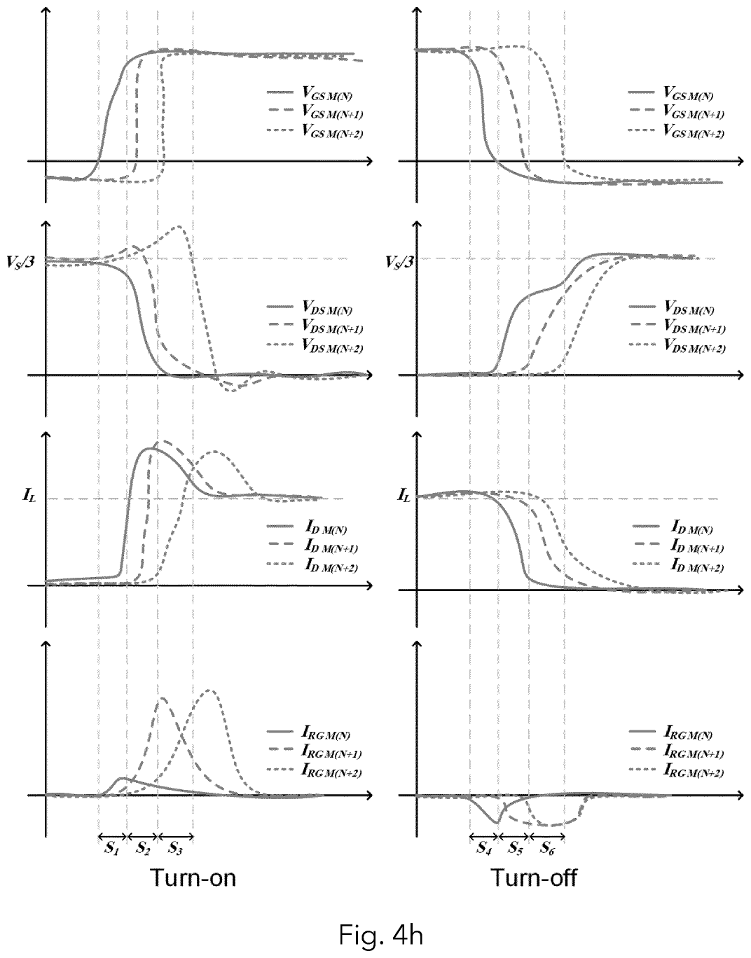

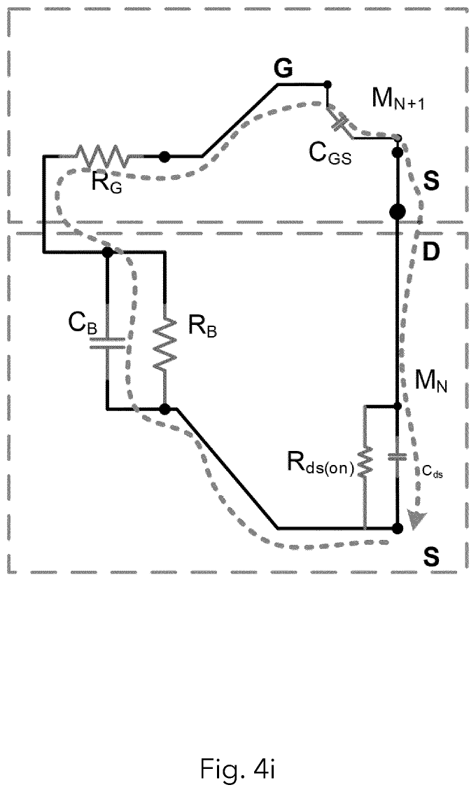

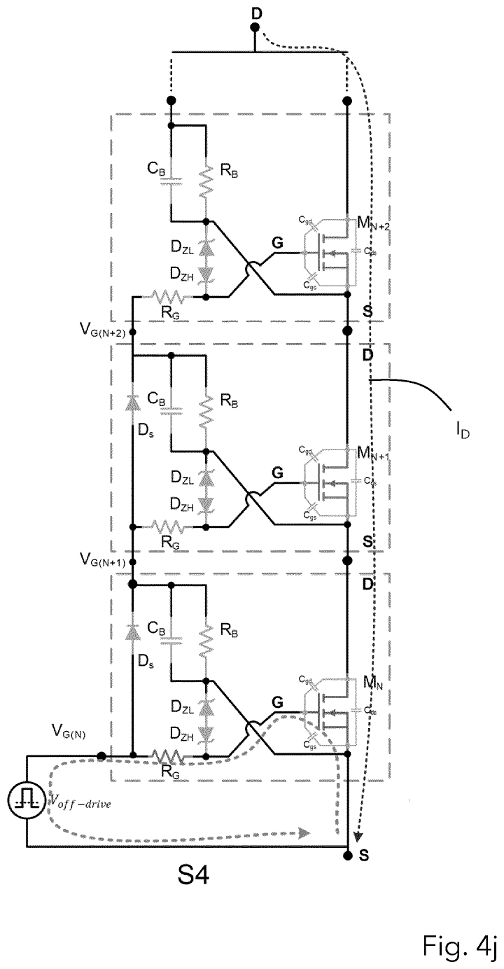

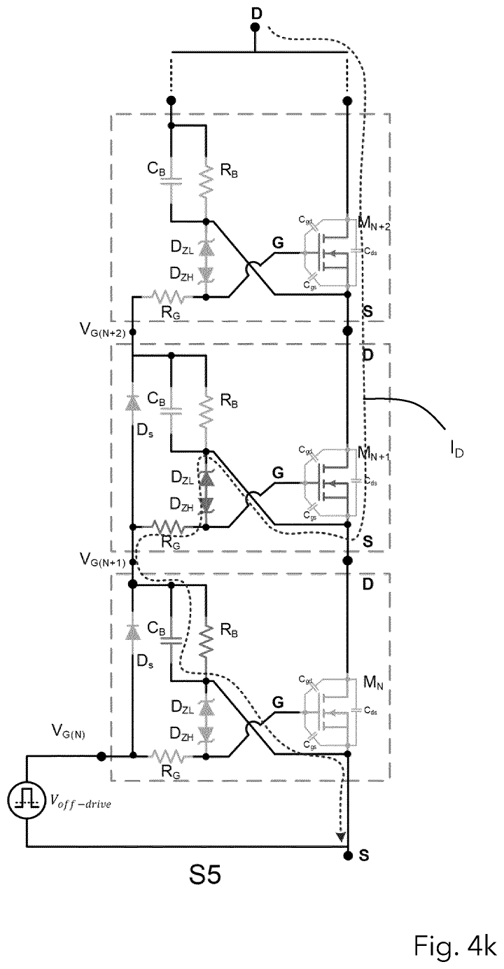

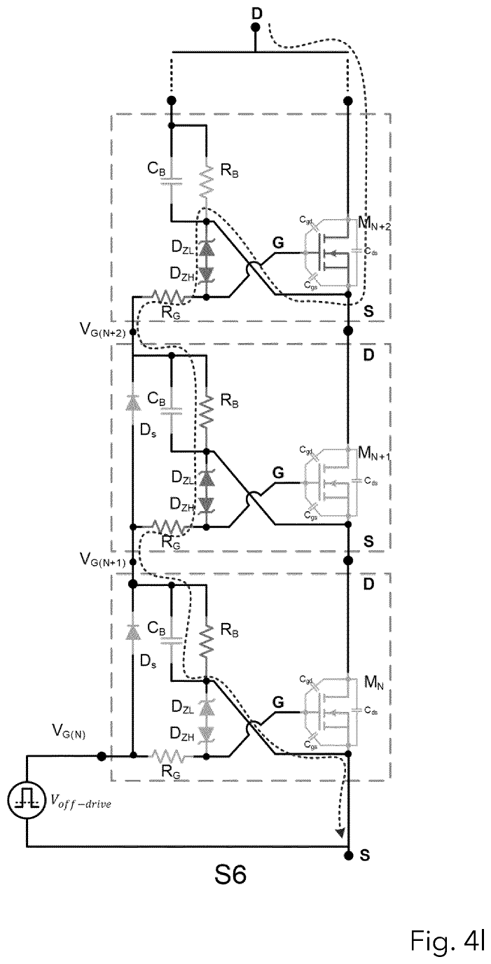

The fourth embodiment is shown in FIGS. 4a and 4b.

### Configuration

Referring to FIG. 4a, there is shown a diagram of a fourth switching circuit 400 in accordance with the present invention. The circuit 400 comprises a MOSFET gate driver 402, first driving cell 404_{N}, a second driving cell 404_{N+1} and a third driving cell 404_{N+2}.

It will be noted that each capacitor C_{B} is initially in a charged state from the supply voltage Vₛ.

The MOSFET driver 402 is known in the art and will not be described in detail here, except to say that it is a circuit configured to provide pulse between V_{on-drive} and V_{off-drive}

The cells 404 are almost identical and shown in more detail in FIG. 4b. The final cell 404_{N+2} in this case may be different making it a “capping cell” which will be discussed below.

Each cell circuit 404_{N} has four terminals:
Cell gate terminal 406;
Cell drain terminal 408;
Cell source terminal 410; and,
Cascading terminal 412.

The cell 404_{N} comprises an SiC n-channel enhancement mode MOSFET M_{N} having gate node G, drain node D and source node S. The MOSFET gate terminal G is connected to the cell gate terminal 406 via a gate resistor R_{G}. The MOSFET drain and source terminals D, S are connected to the cell drain and source terminals 408, 410 respectively. The MOSFET source terminal S is also connected to the cell cascading terminal 412 via a balance resistor R_{B} and a balance capacitor C_{B} in parallel.

A pair of Zener diodes D_{ZL} and D_{ZH} with opposed biases are connected in series (back-to-back) from a first position between the module capacitor/resistor and the MOSFET source terminal S, and a second position between the gate resistor R_{G} and the MOSFET gate terminal G.

The cells 404 are similar to the cell 304_{N} with the exception of the addition of a supply diode DS connecting the gate terminal 406 to the cascading terminal 412, being biased towards the cascading terminal 412.

It will be noted that the cell 404 (aside from the MOSFET M_{N}) is constructed from basic passive components (two resistors, two Zener diodes, one diode and one capacitor). This provides reliability to the design against variations in temperature, frequency and voltages spikes and doesn't include magnetic components that might produce EMI issues and add complexity.

The footprint and selection of these components can be optimized to achieve a compact design. Each cell can provide bipolar driving, gate protection and ON and OFF-state voltage balancing.

### Operation

### OFF—Steady State Operation (FIG. 4c)

It is known that higher junction temperature of the SiC MOSFETs leads to lower gate threshold voltage and a small voltage on the gate might turn on the MOSFET and causes a false turn on, in particular, SiC MOSFETs have less gate capacitance than Si. A negative gate drive voltage is recommended to achieve a stable and reliable off-state of the SiC MOSFETs.

In the present embodiment the supply voltage is used to bias the Zener diodes which will result in a negative voltage which is in this case −5V. FIG. 4c shows the driving cell during the off state.

To bias the Zener diodes, I_{z(min)} should pass through the network (the path of which is shown in dotted line). Each cell 404_{N}, 404_{N+1} etc., has two resistors (R_{B}, R_{G}) and two Zener diodes (D_{ZL}, D_{ZH}). In a proper steady state, one will be forward biased while the other is reversed resulting a negative gate-source.

### Turn on Transition

The explained analysis in this section for the voltage and current waveforms and switching transitions are based on a clamped inductive load in the commonly used double pulse testing. The turn-on transition is divided into three main stages. FIGS. 4d-4f show the current paths during the turn-on transition stages for the three MOSFETs. FIG. 4h illustrates the gate to source voltage (V_{GS}), the drain to source voltage (V_{DS}), the drain currents (I_{D}) and the gate resistance current (I_{RG}) during the transition.

### Stage 1 (FIG. 4d)

It is assumed that before this stage starts, all switches are off and the MOSFETSs are sharing the supply voltage as Vs/n (where n is the total number of MOSFETs) and the V_{GS} is at a negative value (as explained above).

A turn-on signal V_{on-drive} is given by the gate driver 402 to the first MOSFET, M_{N}. The gate voltage starts rising passing the threshold voltage and the MOSFETs are still in off state. The voltage across the MOSFET M_{N}, V_{DSM(N)} is at high voltage and the current I_{DM(N)} is zero. The gate current is dominated by the current through the resistor R_{GM(N)} and 4h shows the current I_{RGM(N)}. The diode D_{SM(N)} is in off state as the voltage across the capacitor C_{BM(N)} is still higher than the drive voltage. The Zener diodes also will not operate as the drive voltage is lower than the protection threshold (+22V).

### Stage 2 (FIG. 4e)

At the beginning of stage 2, the current I_{DM(N)} through the MOSFET M_{N} starts to rise while voltage V_{DSM(N)} of MOSFET My starts to fall bringing the source node of MOSFET M_{N+1} to a lower voltage than the drain node which is illustrated by an overshoot of its voltage V_{DSM(N+1)}.

At the same time, the capacitor C_{BM(N)} will have a new current path to discharge through the gate to source capacitance of M_{N+1} allowing the V_{GSM(N+1)} to rise followed by a rise in its current I_{DM(N+1)} and a fall in its voltage V_{DSM(N+1)}. The discharging current of the capacitor C_{BM(N)} is determined by the change in voltage at the source node of M_{N+1}, caused by the R_{ds(on)M(N)} and the gate capacitance charge of M_{N+1}, in addition, to the value of R_{GM(N+1)}. A basic illustration of the discharging circuit is in FIG. 4i.

Obviously, larger C_{B} produces higher peak current which is required for charging C_{GS} in a fast manner. However, large capacitance leads to longer time to balance the voltages at off-state and reach the steady state. Furthermore, it increases the switching loss when its cell MOSFET is on through its R_{ds(on)}.

### Stage 3 (FIG. 4f)

Similar to stage 2, when MOSFET M_{N+1} is turned on, the voltage at the source node of M_{N+2}, idrops. Consequently, the capacitor C_{BM(N+1)} discharges and the time constant are determined by the value of the path capacitances, R_{GM(N+2)} and R_{BM(N+1)}. Larger values of R_{G} and R_{B} increase the time of discharge and keeps V_{GS} steadier and dissipate less power but it will disturb the turn-off operation dynamics.

### ON—Steady State Operation (FIG. 4g)

At steady state and when all MOSFETs are on, Diode D_{SM(N)} is used to prevent V_{GSM(N+1)} to drop because its gate capacitances will discharge through R_{GM(N+1)} and R_{BM(N)}. Therefore, D_{SM(N)} keeps supplying minimal steady state current. Similar case for D_{SM(N+1)} to keep V_{GSM(N+2)} at sufficient gate voltage level. Larger C_{BM(N)} capacitance provides steadier V_{GSM(N+1)} but it will deteriorate the turn-off time, which is critical in some applications, i.e. high voltage circuit breakers.

As it is shown in FIG. 4g, the last driving cell for M_{N+2} has no supply diode DS because it will create a current path from the driver through D_{SM(N,N+1 . . . )} to the top drain node which has a low voltage due to the MOSFETs being on. This will draw a significant current and decrease the capability of the driver to keep all MOSFETs at on-state properly. For this reason, a “capping cell” is proposed which has the same structure but with no supply diode.

In an alternative embodiment, this diode may be provided, but simply disconnected from the cascading terminal 412 (FIG. 4g shows this).

### Turn Off Transition

FIGS. 4j-4l show the transition during the turn-off and it is divided into three stages.

### Stage 4 (FIG. 4j)

Before this stage, it is assumed that all MOSFETs are in on-steady state and they are conducting the current IDs from the top drain node to the bottom source node through their on-state resistances. At this stage, a negative driving voltage is generated by the driver 402, V_{off-drive}, and discharging the gate capacitance C_{GSM(N)} through R_{GM(N)} as shown in FIG. 4h, the gate voltage drops.

### Stage 5 (FIG. 4k)

The gate voltage V_{GSM(N)} drops to a level below the threshold voltage and the voltage V_{DSM(N)} starts rising while the current I_{DM(N)} starts dropping turning off the MOSFET M(N) completely. The I_{D} through MOSFETs M(N+1) and M(N+2) is commutated through the Zener diodes D_{ZM(N+1)}, the gate resistance R_{GM(N+1)} and the balance resistance R_{BM(N)} to the source terminal as shown in 4k. This current will bias the Zener diode to produce a negative voltage equal to V_{D}_{_{ZL}}_{M(N+1)} across C_{GSM(N+1)}. The applied voltage will start turning off the M(N+1) MOSFET. It is worth mentioning here that R_{BM(N+1)} should be selected to pass the minimum Zener current, I_{z(min)}. It is important to keep the switching time as short as possible to avoid higher dissipation when I_{D} flows through the Zener diodes.

### Stage 6 (FIG. 4l)

Similar to S5, after turning off M(N+1) MOSFET, the current I_{D} will pass through a series of Zener diodes, R_{G}s and R_{B}s to the source node as shown in 4l. This will bias the Zener diode D_{ZLM(N+2)} to turn off the (N+2) MOSFET. Here the combination of R_{B}s should be able to pass the I_{z(min)} through all Zener diodes as we revert to the steady state off condition.

### DESCRIPTION OF THE FIFTH EMBODIMENT

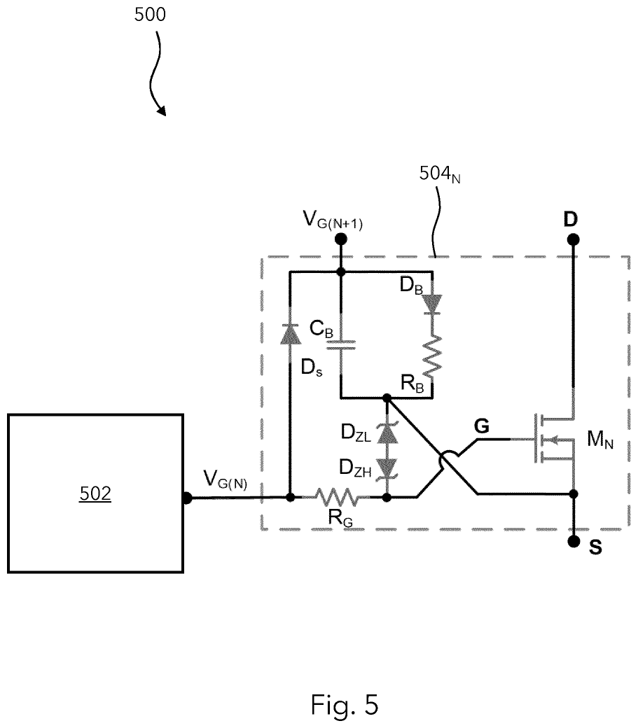

Referring to FIG. 5, a driving cell 504_{N} is shown. The cell 504_{N} is identical to the cell 404_{N} with the exception that a diode D_{B} is added in series with the resistor R_{B}. The diode D_{B} is added to reduce the impact of R_{B} during turn on time.

### DESCRIPTION OF THE SIXTH EMBODIMENT

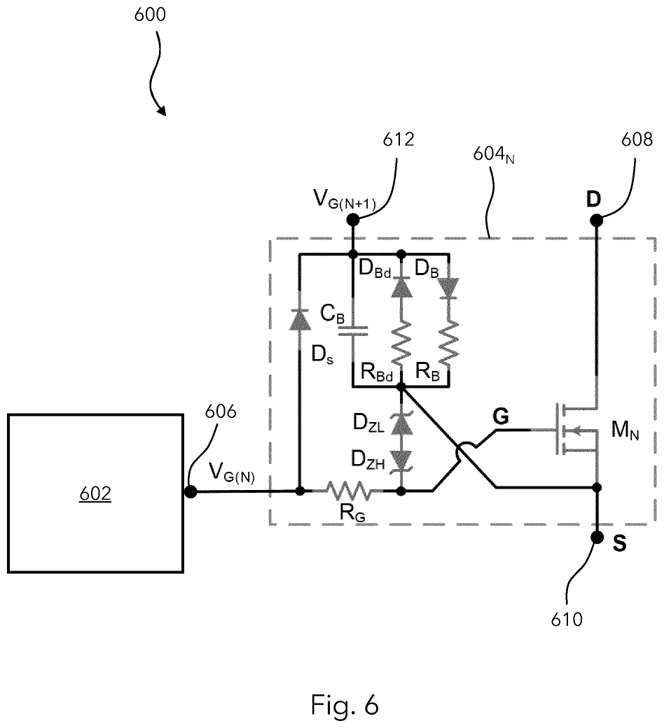

Referring to FIG. 6, a driving cell 604_{N} is shown. The cell 604_{N} is identical to the cell 504_{N} with the exception that a further series diode-resistor pair D_{Bd}/R_{Bd} is added in parallel to the existing diode-resistor pair D_{B}/R_{B}.

The second pair is added to provide more controllability of the dynamics of balancing the voltage during the transient of turn-off state. R_{Bd} can be selected independently from R_{B} and adjusted to the desired settling time and overshoot.

### DESCRIPTION OF THE SEVENTH EMBODIMENT

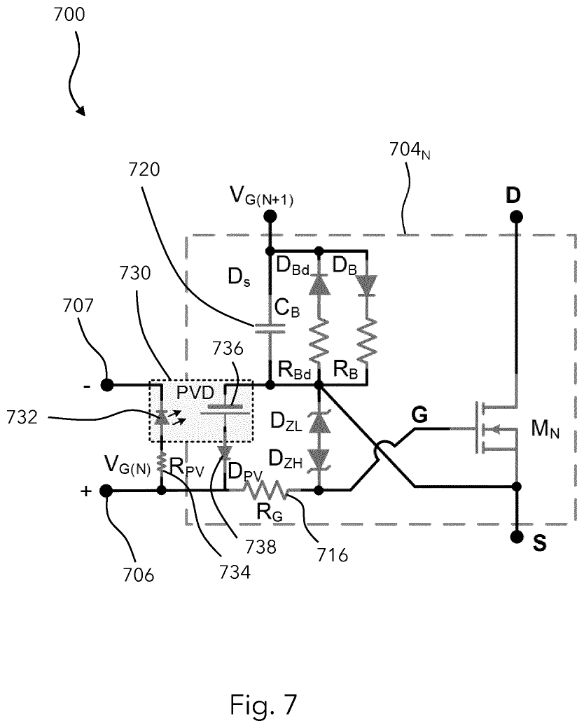

Referring to FIG. 7, a driving cell 704_{N} is shown. The cell 704_{N} is identical to the cell 604_{N} with the exception that a photovoltaic driver PVD 730 has been added.

The PVD 730 comprises on a first side an LED 732 between the cell gate terminal 706 and a negative terminal 707. On a second side, a photovoltaic device 736 is provided between the gate terminal branch (between the gate terminal and the gate resistor 716) and a balance capacitor 720. The LED 732 is arranged such that when a current passes through it (i.e., with a positive or “on” voltage from the gate driver), it emits light to be received by the device 736 and converted into electric current from the gate terminal to the balance capacitor.

An LED resistor 734 is provided between the gate terminal 706 and the LED 732, and a diode 738 provided between the PV device 736 and the gate terminal. The diode 738 only permits current flow from the source terminal S to the gate terminal 706.

### Operation

An gate voltage V_{G(N)} (for example V_{on-drive}, or the voltage from the adjacent module) applied across terminals 706, 707 will activate the LED 732. The LED then emits light which produces a small voltage and current across the PV device 736. The resistor 734 limits the current flowing through the LED as a protection element. The diode 738 protects the PV device 736 from high reverse voltage which might damage it.

The device 736 will maintain the gate terminal voltage higher than the source terminal to ensure a stable on-state for extended periods of time. This is beneficial for very low switching frequency operation or steady state operation, for example in solid-state circuit breakers, modular multilevel converters and configurable batteries.

In another embodiment, several PV devices can be stacked in series and/or parallel to provide higher voltage or current to the gate.

### DESCRIPTION OF THE EIGHTH EMBODIMENT

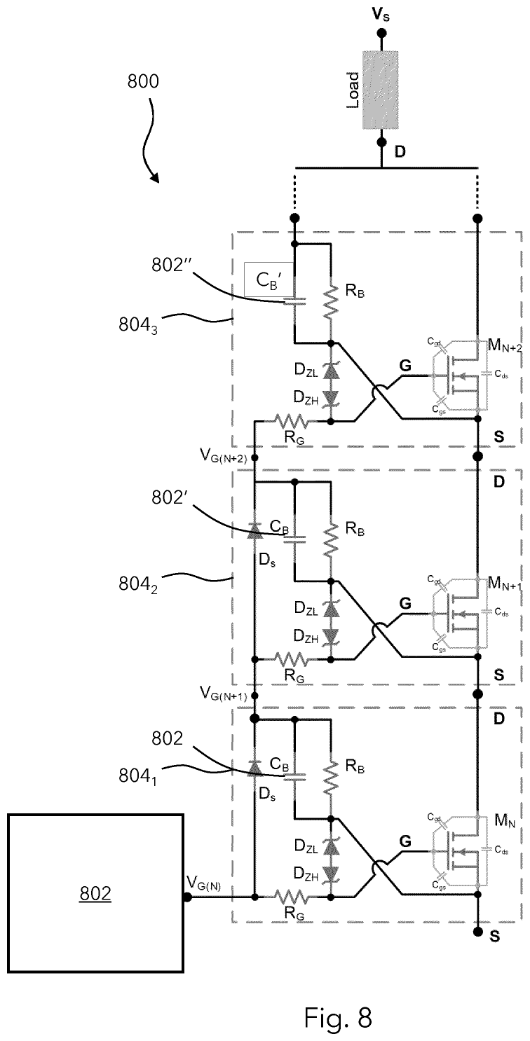

The eighth embodiment is shown in FIG. 8.

### Configuration

The eighth embodiment is a switching circuit 800 in accordance with the present invention. The circuit 800 is substantially identical to the circuit 400. The main difference is that instead of each of the capacitors 802, 802′, 802″ having identical capacitance, the “top” balance capacitor (the one immediately adjacent the load) has a capacitance C_{B}′ higher than the others (which are generally identical). For example, if there are M modules, where N=1, 2 . . . n, then the nth module (the capping cell) will have a balance capacitor with a higher capacitance (and the absent diode as mentioned above). In the example of FIG. 8, n=3 and therefore the capacitance of the balance capacitor of 804₁=that of 804₂=C_{B}, but that of 804₃ has a higher capacitance C_{B}′.

Capacitor 802 of 804₃ therefore carries a higher charge than those below, from the supply voltage Vₛ.

### Operation

In once embodiment, C_{B}′ is 3-5 times the capacitance of C_{B}. This enables “soft switching” moving to the off state.

The first MOSFET at 804₁ at the lower point will switch off first (as described above) bringing higher voltage at its terminal. As the MOSFETs switch off, the capacitor 802″ will tend to absorb the bulk of the current meaning that the MOSFETs will be switching at close to zero current.

### Variations

The above embodiments focus on SiC MOSFETS, although it will be understood that the invention may be applied to MOSFETs using other semiconductor materials, such as Si, and GaN.

The above embodiments also feature n-channel enhancement mode MOSFETs. It will be understood that other types of MOSFETs (p-channel and/or depletion mode) may be employed to suit the application.

1. A switching circuit comprising:
a plurality of n MOSFET cells (n≥2), each MOSFET cell comprising:
a gate terminal, a source terminal, a drain terminal and a cascading terminal;
a MOSFET (M_{N}) having a gate node (G_{N}), source node (S_{N}) and drain node (D_{N}) connected to the gate, source and drain terminals respectively;
a cathode-cathode series connected Zener diode pair between the source node (S_{N}) and the gate node (G_{N});
a gate resistor (R_{G}) between the gate node and a gate terminal;
a balance capacitor (C_{B}) between the source node and the cascading terminal;
a balance resistor (R_{B}) in parallel with the balance capacitor;
a gate driver connected to drive the gate node (G1) of the first MOSFET cell;
wherein:
the drain terminal of each of the MOSFET cells (N=1 . . . (n-1)) is connected to the source terminal of an adjacent, MOSFET cell (N=2 . . . n);
the cascading terminal of each of the MOSFET cells (N=1 . . . (n-1)) is connected to the gate terminal of an adjacent, MOSFET cell (N=2 . . . n); and,
the drain terminal and cascading terminal of the nth MOSFET cell (N=n) is connected to a supply voltage (Vs);
such that:
in an off state, the supply voltage (Vs) provided across the cascading terminal of the nth cell and the source terminal of the first cell charges the balance capacitor C_{B} of each cell; and,
upon provision of a gate driving voltage to the gate terminal of the first cell (N=1) to activate the MOSFET (M₁) of the first cell, the balance capacitor (C₁) discharges to the gate terminal of the adjacent cell to switch on the MOSFET (M₂) thereof.

2. The switching circuit according to claim 1, wherein n≥2, and upon activation of the MOSFET (M₂) of the second cell, the balance capacitor (C₂) discharges to the gate terminal of the adjacent cell to switch the MOSFET (M₃) thereof.

3. The switching circuit according to claim 1, wherein each MOSFET cell comprises a supply diode DS directed from the gate terminal to the cascading terminal.

4. The switching circuit according to claim 3, wherein the supply diode D_{S} can be selectively disconnected in the final cell (N=n).

5. The switching circuit according to claim 1, wherein each MOSFET cell from N=1 to N=(n-1) comprises a supply diode D_{S} directed from the gate terminal to the cascading terminal.

6. The switching circuit according to claim 1, wherein the balance capacitor of the MOSFET cell N=n has a capacitance at least twice as high as the balance capacitors of the MOSFET cells N=1 to N=(n-1).

7. The switching circuit according to claim 6, wherein capacitance of the balance capacitors of the MOSFET cells N=1 to N=(n-1) are identical.

8. The switching circuit according to claim 1, wherein each MOSFET cell comprises a balance diode D_{B} in series with the balance resistor R_{B}, the balance diode directed from the cascading terminal to the source node.

9. The switching circuit according to claim 7, wherein each MOSFET cell comprises a second balance resistor D_{Bd}, and a second balance diode D_{Bd} in series with the balance resistor R_{Bd}, the second balance diode D_{Bd} being directed from the source node to the cascading terminal, wherein the balancing resistors have different resistances.

10. The switching circuit according to claim 1, wherein the supply voltage Vₛ>2 kV.

11. A switching circuit cell, comprising:
a gate terminal, a source terminal, a drain terminal and a cascading terminal;
a MOSFET (M_{N}) having a gate node (G_{N}), source node (S_{N}) and drain node (D_{N}) connected to the gate, source and drain terminals respectively;
a gate resistor (R_{G}) between the gate node and a gate terminal;
a balance capacitor (C_{B}) between the source node and the cascading terminal;
a balance resistor (R_{B}) in parallel with the balance capacitor; and
a gate driver connected to drive the gate node (G₁) of the first MOSFET cell;
wherein the switching circuit cell is configured to be connected with a gate driver and at least one like cell in series to provide a high voltage switching circuit.
